(19) United States
(12) Patent Application Publication
(10) Pub. No.: US 2025/0351573 A1
(43) Pub. Date: Nov. 13, 2025

(54) DISPLAY DEVICE AND METHOD FOR FABRICATING THE SAME

(71) Applicant: Samsung Display Co., LTD., Yongin-si (KR)

(72) Inventors: Dong Jin PARK, Yongin-si (KR); Sung Hyun KIM, Yongin-si (KR)

(73) Assignee: Samsung Display Co., LTD., Yongin-si (KR)

(21) Appl. No.: 19/012,021

(22) Filed: Jan. 7, 2025

(30) Foreign Application Priority Data
May 7, 2024 (KR) 10-2024-0059758

(51) Int. Cl. H10D 86/01; C30B 28/02; C30B 29/06; H10D 86/40; H10K 59/12; H10K 59/121

(52) U.S. Cl. CPC H10D 86/0229; C30B 28/02; C30B 29/06; H10D 86/421; H10K 59/1201; H10K 59/1213

(57) ABSTRACT

A display device and a method of fabricating the display device are provided. The method of fabricating a display device, the method comprises forming a metal layer on a substrate, forming a buffer layer on the metal layer, forming an amorphous silicon layer on the buffer layer, aligning a crystallization device that converts microwaves into magnetic fields above the amorphous silicon layer, scanning the crystallization device above the amorphous silicon layer to generate resistance heat in the metal layer by the magnetic fields, and crystallizing the amorphous silicon layer into a polycrystalline silicon layer using the resistance heat of the metal layer.

### CROSS-REFERENCE TO RELATED APPLICATION(S)

This application claims priority to and benefits of Korean Patent Application No. 10-2024-0059758 filed on May 7, 2024 in the Korean Intellectual Property Office, the entire contents of which are incorporated herein by reference.

### BACKGROUND

### 1. Technical Field

The disclosure relates to a display device and a method of fabricating the display device.

### 2. Description of the Related Art

As the information-oriented society evolves, various demands for display devices are ever increasing. Display devices may be a liquid-crystal display device, a field emission display device, a light-emitting display device, or the like. Light-emitting display devices may include an organic light-emitting display device including organic light-emitting diodes as light-emitting elements, an inorganic light-emitting display device including inorganic light-emitting diodes as light-emitting elements, etc.

In a display device, thin-film transistors may be used to control whether each pixel emits light and the luminance of each pixel. A thin-film transistor includes a semiconductor layer, a gate electrode, and source/drain electrodes. Polycrystalline silicon (poly-Si), which is crystallized amorphous silicon (a-Si), is mainly used for the semiconductor layer. As a method for annealing to crystallize amorphous silicon (a-Si) into polysilicon (p-Si), laser annealing is used, which crystallizes amorphous silicon (a-Si) by irradiating a laser beam. However, the laser annealing has a problem in that hillocks may be generated on a surface of polycrystalline silicon, thereby reducing electron mobility.

### SUMMARY

Aspects of the disclosure provide a display device capable of improving tack time and characteristics of a semiconductor layer, and a method of fabricating the display device.

It should be noted that objects of the disclosure are not limited to the above-mentioned object; and other objects of the disclosure will be apparent to those skilled in the art from the following descriptions.

According to an aspect of the disclosure, a method of fabricating a display device, the method may include forming a metal layer on a substrate, forming a buffer layer on the metal layer, forming an amorphous silicon layer on the buffer layer, aligning a crystallization device that converts microwaves into magnetic fields above the amorphous silicon layer, scanning the crystallization device above the amorphous silicon layer to generate resistance heat in the metal layer by the magnetic fields, and crystallizing the amorphous silicon layer into a polycrystalline silicon layer using the resistance heat of the metal layer.

In an embodiment, a frequency of the microwave may be in a range of about 1 MHz to about 300 GHz.

In an embodiment, the scanning may be performed at a scan speed of 1 to 100 mm/s.

In an embodiment, the resistance heat of the metal layer may be in a range of about 400 to about 1,000° C.

In an embodiment, a grain size of the polycrystalline silicon layer may be in a range of about 1 μm to about 10 μm.

In an embodiment, the crystallization device may include a microwave input where microwaves are supplied, a coupler that adjusts an amount of the microwaves supplied from the microwave input, a dielectric resonator that is spaced apart from the coupler and generates magnetic fields by resonating with the microwaves transmitted from the coupler, and a body in which the microwave input, the coupler and the dielectric resonator may be disposed.

In an embodiment, the crystallization device may be a microwave induction heating annealing device.

In an embodiment, an induced current may be generated in the metal layer by the magnetic fields, and the resistance heat may be generated by the induced current.

In an embodiment, a thickness of the metal layer may be in a range of about 1 μm to about 300 μm.

In an embodiment, the buffer layer may be formed by stacking an upper layer made of silicon oxide on a lower layer including polyimide.

In an embodiment, the method may further include patterning the polycrystalline silicon layer to form a semiconductor layer.

In an embodiment, the method may further include forming a gate insulating layer on the semiconductor layer, forming a gate electrode overlapping the semiconductor layer on the gate insulating layer, forming an interlayer dielectric layer on the gate electrode, and forming a thin-film transistor by forming a source electrode and a drain electrode respectively connected to the semiconductor layer on the interlayer dielectric layer.

In an embodiment, the method may further include forming a pixel electrode connected to the thin-film transistor on the thin-film transistor, forming a light emitting layer on the pixel electrode, and forming a light-emitting element by forming a common electrode on the emissive layer.

According to an aspect of the disclosure, a display device may include a substrate, a metal layer disposed on the substrate, a buffer layer disposed on the metal layer, a semiconductor layer disposed on the buffer layer and including polycrystalline silicon, a gate insulating layer disposed on the semiconductor layer, a gate electrode disposed on the gate insulating layer, an interlayer dielectric layer disposed on the gate electrode, and a source electrode and a drain electrode disposed on the interlayer dielectric layer and respectively connected to the semiconductor layer, wherein a grain size of the polycrystalline silicon may be in a range of about 1 μm to about 10 μm.

In an embodiment, a thickness of the metal layer may be in a range of about 1 μm to about 300 μm.

In an embodiment, the metal layer may be disposed on an entire upper surface of the substrate.

In an embodiment, the metal layer may include at least one of copper (Cu), aluminum (Al), gold (Au), silver (Ag), titanium (Ti), molybdenum (Mo), tungsten (W), sodium (Na), chromium (Cr), iron (Fe), nickel (Ni), zinc (Zn), neodymium (Nb) and tantalum (Ta).

In an embodiment, the buffer layer may include a lower layer including polyimide and an upper layer made of silicon oxide.

In an embodiment, the display device may further include a pixel electrode connected to the source electrode or the drain electrode.

In an embodiment, the display device may further include a light emitting layer disposed on the pixel electrode, and a common electrode disposed on the light emitting layer.

According to an aspect of the disclosure, an electronic device, comprises a display device that provides an image, a processor that provides an image data signal to the display device, a memory that stores a data information for operation, and a power module that generates power, wherein the display device comprises, a substrate, a metal layer disposed on the substrate, a buffer layer disposed on the metal layer, a semiconductor layer disposed on the buffer layer and including polycrystalline silicon, a gate insulating layer disposed on the semiconductor layer, a gate electrode disposed on the gate insulating layer, an interlayer dielectric layer disposed on the gate electrode, and a source electrode and a drain electrode disposed on the interlayer dielectric layer and respectively connected to the semiconductor layer, wherein a grain size of the polycrystalline silicon is in a range of about 1 μm to about 10 μm.

A method of fabricating a display device according to an embodiment may crystallize an amorphous silicon layer into a polycrystalline silicon layer by generating resistance heat in a metal layer using a crystallization device that generates magnetic fields. The metal layer may increase the grain size by uniformly heating throughout the surface of the amorphous silicon layer. For example, by increasing the grain size of the polycrystalline silicon layer, the grain boundaries may be reduced and defects may be reduced. Since a laser is not used, it is possible to prevent hillocks caused by interference of laser beams.

According to an embodiment of the disclosure, a display device includes a semiconductor layer crystallized through a high resistance heat of a metal layer, so that the grain size may be increased. As a result, high-speed operation is possible by increasing electron mobility, defects in the semiconductor layer may be reduced, and leakage current may be prevented.

It should be noted that effects of the disclosure are not limited to those described above and other effects of the disclosure will be apparent to those skilled in the art from the following descriptions.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view showing a display device according to an embodiment.

FIG. 2 is a schematic view showing lines included in the display device according to the embodiment.

FIG. 3 is a schematic diagram of an equivalent circuit of a sub-pixel according to an embodiment.

FIG. 4 is a schematic cross-sectional view showing a sub-pixel of a display device according to an embodiment.

FIG. 5 is a schematic view showing a crystallization device according to an embodiment.

FIG. 6 is a schematic view graphically illustrating an operating principle of the crystallization device.

FIGS. 7 to 13 are schematic views showing processing steps of a method of fabricating a display device according to an embodiment.

FIG. 14 is a block diagram of an electronic device according to one embodiment.

FIG. 15 is a schematic diagram of an electronic device according to various embodiments.

### DETAILED DESCRIPTION OF THE EMBODIMENTS

The invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that in case that a layer is referred to as being “on” another layer or substrate, it may be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the invention. Similarly, the second element could also be termed the first element.

Each of the features of the various embodiments may be combined or combined with each other, in part or in whole, and technically various interlocking and driving are possible. Each embodiment may be implemented independently of each other or may be implemented together in an association.

Hereinafter, embodiments will be described with reference to the accompanying drawings.

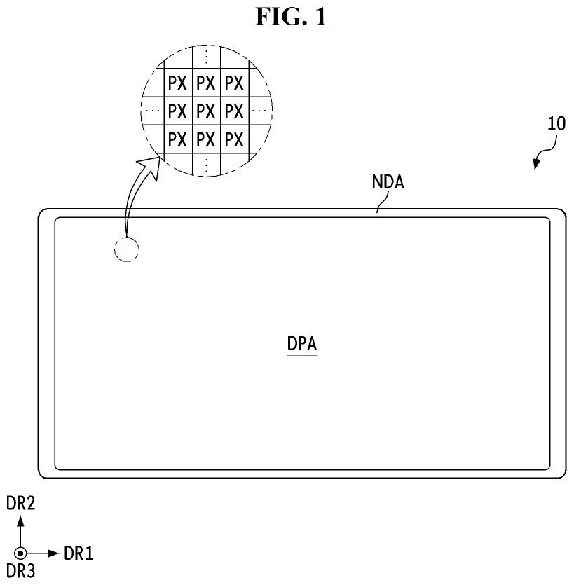

FIG. 1 is a schematic plan view showing a display device according to an embodiment.

As used herein, the terms “above,” “top” and “upper surface” refer to the upper side of a display device 10, i.e., the side indicated by the arrow in the third direction DR3, whereas the terms “below,” “bottom” and “lower surface” refer to the opposite side in the third direction DR3. As used herein, the terms “left,” “right,” “upper” and “lower” sides indicate relative positions in case that the display device 10 is viewed from the top. For example, the “right side” refers to the side indicated by the arrow of the first direction DR1, the “left side” refers to the opposite side to the side indicated by the arrow of the first direction DR1, the “upper side” refers to the side indicated by the arrow of the second direction DR2, and the “lower side” refers to the opposite side to the side indicated by the arrow the second direction DR2.

Referring to FIG. 1, the display device 10 may display a moving image or a still image. A display device 10 may refer to any electronic device that provides a display screen. For example, the display device 10 may include a television set, a laptop computer, a monitor, an electronic billboard, the Internet of Things (IoT) devices, a mobile phone, a smart phone, a tablet personal computer (PC), an electronic watch, a smart watch, a watch phone, a head-mounted display device, a mobile communications terminal, an electronic notebook, an electronic book, a portable multimedia player (PMP), a navigation device, a game console and a digital camera, a camcorder, etc.

The display device 10 may include a display panel for providing a display screen. Examples of the display panel may include an inorganic light-emitting diode display panel, an organic light-emitting display panel, a quantum-dot light-emitting display panel, a plasma display panel, a field emission display panel, etc. In the following description, an inorganic light-emitting diode display panel is employed as an example of the display panel, but embodiments are not limited thereto. Any other display panel may be used as long as the technical idea of the disclosure may be applied in the same manner.

The shape of the display device 10 may be modified in a variety of ways. For example, the display device 10 may have shapes such as a rectangle having longer lateral sides, a rectangle having longer vertical sides, a square, a quadrangle having rounded corners (vertices), other polygons, a circle, etc. The shape of a display area DPA of the display device 10 may also be similar to the overall shape of the display device 10. FIG. 1 shows the display device 1 in the shape of a rectangle with longer horizontal sides and the display area DPA.

The display device 10 may include a display area DPA and a non-display area NDA. In the display area DPA, images may be displayed. In the non-display area NDA, images may not be displayed. The display area DPA may be referred to as an active area, while the non-display area NDA may also be referred to as an inactive area. The display area DPA may generally occupy the center portion of the display device 10.

The display area DPA may include pixels PX. The pixels PX may be arranged in a matrix. The shape of each pixel PX may be a rectangle or a square when viewed from the top (or in plan view), but embodiments are not limited thereto. Each pixel may have a diamond shape having sides inclined with respect to a direction. In another example, the pixels PX may be arranged in stripes or the PenTile™ pattern. Each of the pixels PX may include at least one light-emitting element EL that emits light of a particular wavelength band to represent a color.

The non-display area NDA may be disposed around the display area DPA. The non-display area NDA may surround the display area DPA entirely or partially. The display area DPA may have a rectangular shape, and the non-display area NDA may be disposed to be adjacent to the four sides of the display area DPA. The non-display area NDA may form the bezel of the display device 10. Lines or circuit drivers included in the display device 10 may be disposed in each of the non-display area NDA, or external devices may be mounted.

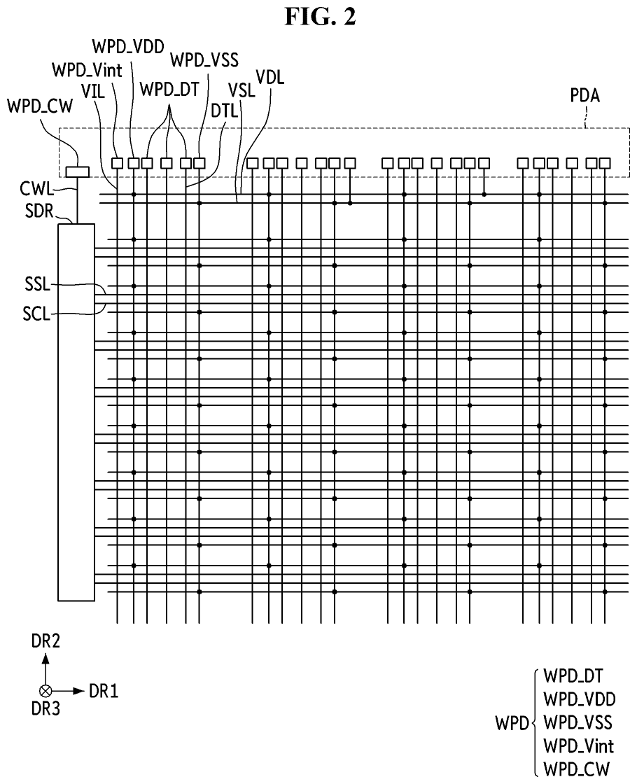

FIG. 2 is a schematic view showing lines included in the display device according to the embodiment.

Referring to FIG. 2, the display device 10 may include a plurality of lines. The plurality of lines may include a scan line SCL, a sensing line SSL, a data line DTL, an initialization voltage line VIL, a first voltage line VDL, a second voltage line VSL, etc. For example, although not shown in the drawings, other lines may be further disposed in the display device 10.

The scan line SCL and the sensing line SSL may be extended in the first direction DR1. The scan line SCL and the sensing line SSL may be connected to a scan driver SDR. The scan driver SDR may include a driving circuit. The scan driver SDR may be disposed on a side of the display area DPA in the first direction DR1. The scan driver SDR may be connected to a signal line pattern CWL, and at least one end portion of the signal line pattern CWL may form a pad WPD_CW on the non-display area NDA to be connected to an external device, but embodiments are not limited thereto.

As used herein, in case that an element is referred to as being “connected” or “coupled” to another element, it may be directly connected or coupled to the element or intervening elements may be present. For example, such elements may be understood as a single integrated element and thus one portion thereof is connected to another portion. Moreover, in case that an element is referred to as being “connected” to another element, it may be in direct contact with the element and also electrically connected to the element.

The data line DTL and the initialization voltage line VIL may be extended in the second direction DR2 crossing the first direction DR1. The first voltage line VDL and the second voltage line VSL may be extended in the first direction DR1 and the second direction DR2. The first voltage line VDL and the second voltage line VSL may be formed as conductive layers in which the parts extended in the first direction DR1 and the parts extended in the second direction DR2 are disposed on different layers, and may have a mesh structure on the front surface of the display area DPA. However, embodiments are not limited thereto. Each of the pixels PX of the display device 10 may be connected to at least one data line DTL, the initialization voltage line VIL, the first voltage line VDL, and the second voltage line VSL.

The data line DTL, the initialization voltage line VIL, the first voltage line VDL and the second voltage line VSL may be electrically connected to one or more wire pads WPD. The wire pads WPD may be disposed in the non-display areas NDA. According to an embodiment, a wire pad WPD_DT of the data line DTL (hereinafter referred to as a data pad), a wire pad WPD_Vint of the initialization voltage line VIL (hereinafter referred to as an initialization voltage pad), a wire pad WPD_VDD of the first voltage line VDL (hereinafter referred to as a first power pad), and a wire pad WPD_VSS of the second voltage line VSL (hereinafter referred to as a second power pad) may be disposed in the pad area PDA on a side of the display area DPA in the second direction DR2. External devices may be mounted on the wire pads WPD. External devices may be mounted on the wire pads WPD by an anisotropic conductive film, ultrasonic bonding, etc.

Each of the pixels PX or sub-pixels SPXn of the display device 10 may include a pixel driving circuit, where n is an integer of 1 to 3. The above-described lines may pass through each of the pixels PX or the periphery of each of the pixels PX to apply a driving signal to the pixel driving circuit. The pixel driving circuit may include transistors and a capacitor. The numbers of transistors and capacitors of each pixel driving circuit may be changed in a variety of ways. According to an embodiment, each of the sub-pixels SPXn of the display device 10 may have a 3T-1C structure, e.g., a pixel driving circuit, may include three transistors and one capacitor. In the following description, the pixel driving circuit having the 3T-1C structure will be described as an example. However, embodiments are not limited thereto. A variety of modified pixel structures may be employed such as a 2T-1C structure, a 7T-1C structure and a 6T-1C structure.

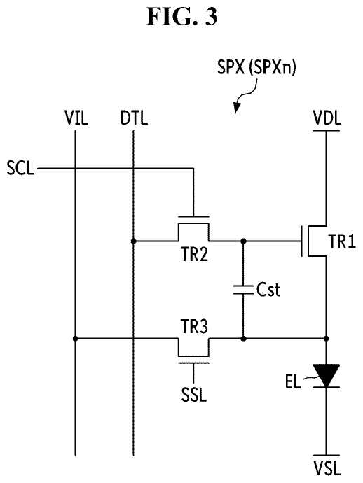

FIG. 3 is a schematic diagram of an equivalent circuit of a sub-pixel according to an embodiment.

Referring to FIG. 3, each of the sub-pixels SPXn of the display device 10 according to an embodiment may include three transistors TR1, TR2 and TR3 and one storage capacitor Cst in addition to a light-emitting element EL.

The light-emitting element EL may emit light in proportional to the current supplied through the first transistor TR1. The light-emitting element EL may include a first electrode, a second electrode, and at least one light emitting layer disposed between the first and second electrodes. The light emitting layer may emit light in a particular wavelength range by an electric signal transmitted from the first electrode and the second electrode.

An end portion of the light-emitting element EL may be connected to a source electrode of the first transistor TR1, and another end portion of the light-emitting element EL may be connected to the second voltage line VSL from which a low-level voltage (hereinafter referred to as a second supply voltage) lower than a high-level voltage (hereinafter referred to as a first supply voltage) of the first voltage line VDL is applied. For example, the another end portion of the light-emitting element EL may be connected to a source electrode of the second transistor TR2.

The first transistor TR1 may adjust a current flowing from the first voltage line VDL from which the first supply voltage is supplied to the light-emitting element EL according to the voltage difference between a gate electrode and the source electrode. For example, the first transistor TR1 may be a driving transistor for driving the light-emitting element EL. The gate electrode of the first transistor TR1 may be connected to a source electrode of the second transistor TR2, the source electrode of the first transistor TRI may be connected to the first electrode of the light-emitting element EL, and the drain electrode of the first transistor TR1 may be connected to the first voltage line VDL from which the first supply voltage is applied.

The second transistor TR2 may be turned on by a scan signal of the scan line SCL to connect the data line DTL to the gate electrode of the first transistor TR1. The gate electrode of the second transistor TR2 may be connected to the scan line SCL, the source electrode of the second transistor TR2 may be connected to the gate electrode of the first transistor TR1, and the drain electrode of the second transistor TR2 may be connected to the data line DTL.

The third transistor TR3 may be turned on by a sensing signal of the sensing line SSL to connect the initialization voltage line VIL to an end portion of the light-emitting element EL. The gate electrode of the third transistor TR3 may be connected to the sensing line SSL, the drain electrode of the third transistor TR3 may be connected to the initialization voltage line VIL, and the source electrode of the third transistor TR3 may be connected to an end portion of the light-emitting element EL or the source electrode of the first transistor TR1.

The source electrode and the drain electrode of each of the transistors TR1, TR2 and TR3 are not limited to those described above. They may be connected in the opposite way. For example, each of the transistors TR1, TR2 and TR3 may be formed as a thin-film transistor. For example, although each of the transistors TR1, TR2 and TR3 implemented as an n-type metal oxide semiconductor field effect transistor (MOSFET) in the example shown in FIG. 3, embodiments are not limited thereto. For example, each of the transistors TR1, TR2 and TR3 may be implemented as a p-type MOSFET, or some of the transistors T1, T2 and T3 may be implemented as n-type MOSFETs while the others may be implemented as p-type MOSFETs.

The storage capacitor Cst may be formed between the gate electrode and the source electrode of the first transistor TR1. The storage capacitor Cst may store a voltage difference between the gate voltage and the source voltage of the first transistor TR1.

Hereinafter, the structure of a sub-pixel SPX of a display device 10 according to an embodiment will be described in detail with reference to other drawings.

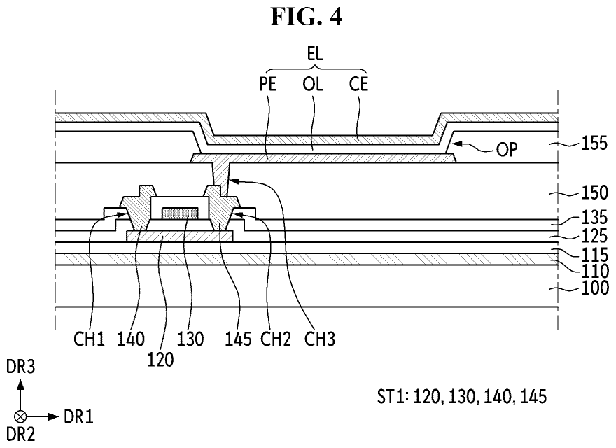

FIG. 4 is a schematic cross-sectional view showing a sub-pixel of a display device according to an embodiment.

Referring to FIG. 4, a metal layer 110 may be disposed on a substrate 100. The substrate 100 may be a rigid substrate or a flexible substrate that is bendable, foldable, rollable, and so on. The substrate 100 may be made of an insulating material such as glass, quartz and a polymer resin. The examples of the polymer material may be polyethersulphone (PES), polyacrylate (PA), polyacrylate (PAR), polyetherimide (PEI), polyethylenenapthalate (PEN), polyethyleneterepthalate (PET), polyphenylenesulfide (PPS), polyallylate, polyimide (PI), polycarbonate (PC), cellulosetriacetate (CAT), cellulose acetate propionate (CAP), or combinations thereof. The substrate 100 may include a metal material.

The metal layer 110 may be disposed (e.g., entirely disposed) on the substrate 100. For example, the metal layer 110 may be disposed (e.g., entirely disposed) on the upper surface of the substrate 100. The metal layer 110 may generate heat in a crystallization process described later to crystallize an amorphous silicon layer.

The metal layer 110 may contain a metal material that generates an induced current to generate resistance heat. For example, the metal material may include one or more of copper (Cu), aluminum (Al), gold (Au), silver (Ag), titanium (Ti), molybdenum (Mo), tungsten (W), sodium (Na), chromium (Cr), iron (Fe), nickel (Ni), zinc (Zn), neodymium (Nb) and tantalum (Ta).

The metal layer 110 may be made up of a single-layer structure or a multi-layer structure of the above-described metal materials. In case that the metal layer 110 has a two-layer structure, the upper layer may be a metal capable of generating high-temperature resistance heat, and the lower layer may be a metal having low thermal conductivity from the upper layer. For example, in case that the upper layer is copper, the lower layer may be a metal having lower thermal conductivity than copper, such as aluminum.

The thickness of the metal layer 110 may be in a range of about 1 μm to about 300 μm. In order to readily generate resistance heat by induced current, the thickness of the metal layer 110 should be equal to or greater than about 1 μm. In order to prevent the process tack time for forming the metal layer 110 from increasing, the thickness of the metal layer 110 should be equal to or less than about 300 μm.

As the metal layer 110 is disposed (e.g., entirely disposed) on the substrate 100, it may evenly transfer heat generated in case that the display device 10 is driven, so that it is possible to reduce an increase in the temperature of the display device 10. For example, it is possible to block electromagnetic waves that occur from outside or inside.

A buffer layer 115 may be disposed on the metal layer 110. The buffer layer 115 may be made of an inorganic material, an organic material, or a multilayer thereof which prevents the permeation of air or moisture. In case that the buffer layer 115 includes an inorganic material, the inorganic material may include, for example, silicon oxide, silicon nitride, silicon oxynitride, aluminum oxide, tantalum oxide, hafnium oxide, zirconium oxide, titanium oxide, or a combination thereof.

In case that the buffer layer 115 includes an organic material, the organic material may include, for example, polyimide (PI), polyacrylate (PA), or a combination thereof.

In case that the buffer layer 115 includes an inorganic material and an organic material, the buffer layer 115 may include a lower layer made of the organic material and an upper layer made of the inorganic material. For example, the buffer layer 115 may have a structure in which a lower layer made of polyimide and an upper layer made of silicon oxide are stacked on one another.

A first switching element ST1 may be disposed on the buffer layer 115. The first switching element ST1 may include a semiconductor layer 120, a gate electrode 130, a source electrode 140, and a drain electrode 145. The first switching element ST1 may form a pixel circuit for each of pixels. For example, the first switching element ST1 may be a driving transistor or a switching transistor of a pixel circuit. While only one transistor is disposed in the sub-pixel SPX of the display device 10 in the drawing, the transistor may correspond to the above-described first transistor TR1 of FIG. 3.

The semiconductor layer 120 may be disposed on the buffer layer 115. The semiconductor layer 120 may be disposed to overlap (e.g., partially overlap) the gate electrode 130 of a first conductive layer, which will be described later.

The semiconductor layer 120 may include polycrystalline silicon. For example, the semiconductor layer 120 may include polycrystalline silicon obtained by crystallizing amorphous silicon by a process of fabricating a display device, which will be described later.

The semiconductor layer 120 may be formed by crystallizing (e.g., completely crystallizing) the amorphous silicon layer disposed on the substrate 100 and then patterning the amorphous silicon layer. In another example, the semiconductor layer 120 may be formed by patterning the amorphous silicon layer and then crystallizing the patterned amorphous silicon pattern. However, embodiments are not limited thereto. By crystallizing only a portion of the amorphous silicon layer, the semiconductor layer 120 may include both an amorphous silicon region in which amorphous silicon is disposed and a polycrystalline silicon region in which polycrystalline silicon is disposed.

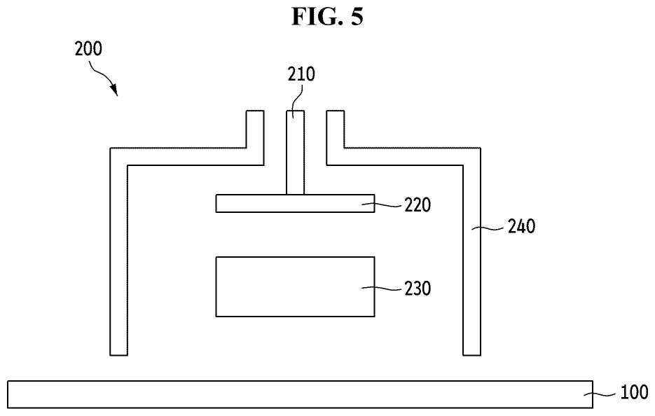

According to an embodiment, the semiconductor layer 120 may include polycrystalline silicon crystallized by a method to be described later. The polycrystalline silicon of the semiconductor layer 120 may be crystallized using microwave induction heating annealing by a crystallization device 200 (see FIG. 5) to be described later, so that the grain size of the silicon may be increased. By using the microwave induction heating annealing, the grain size may become larger because the surface of the amorphous silicon layer is equally heated by the metal layer 110. For example, the grain size of polycrystalline silicon of the semiconductor layer 120 may be in a range of about 1 μm to about 10 μm.

According to this embodiment, by increasing the grain size of silicon of the semiconductor layer 120, electron mobility may be increased and defects may be reduced. As a result, it is possible to implement a display device allowing thin-film transistors to be driven at high speed.

A gate insulating layer 125 may be disposed on the semiconductor layer 120. The gate insulating layer 125 may be disposed on the substrate 100 including the semiconductor layer 120. The gate insulating layer 125 may work (or function) as a gate insulating film of the first switching element ST1.

The gate insulating layer 125 may include an inorganic material, e.g., a silicon compound, a metal oxide, or a combination thereof. For example, the gate insulating layer 125 may include silicon oxide, silicon nitride, silicon oxynitride, aluminum oxide, tantalum oxide, hafnium oxide, zirconium oxide, titanium oxide, or a combination thereof. The gate insulating layer 125 may be made up of a single layer or multiple layers of different materials stacked on one another.

The gate electrode 130 may be disposed on the gate insulating layer 125. The gate electrode 130 may overlap a channel region of the semiconductor layer 120 in the thickness direction, e.g., the third direction DR3. The gate electrode 130 may include a metal. For example, the gate electrode 130 may include at least one metal selected from the group consisting of molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W) and copper (Cu).

An interlayer dielectric layer 135 may be disposed on the gate electrode 130. The interlayer dielectric layer 135 may be disposed on the gate electrode 130 and the gate insulating layer 125. The interlayer dielectric layer 135 may work (or function) as an insulating film between the gate electrode 130 and other layers disposed on the gate electrode 130. For example, the interlayer dielectric layer 135 may cover the gate electrode 130 to protect the gate electrode 130.

The interlayer dielectric layer 135 may include a silicon compound, a metal oxide, or a combination thereof. For example, the interlayer dielectric layer 135 may include silicon oxide, silicon nitride, silicon oxynitride, aluminum oxide, tantalum oxide, hafnium oxide, zirconium oxide, titanium oxide, or a combination thereof. The interlayer dielectric layer 135 may be made up of a single layer or multiple layers of different materials stacked on one another.

The source electrode 140 and the drain electrode 145 may be disposed on the interlayer dielectric layer 135. The source electrode 140 may be connected to the semiconductor layer 120 through a first contact hole CH1 penetrating the interlayer dielectric layer 135 and the gate insulating layer 125. The drain electrode 145 may be connected to the semiconductor layer 120 through a second contact hole CH2 penetrating the interlayer dielectric layer 135 and the gate insulating layer 125.

The source electrode 140 and the drain electrode 145 may include at least one metal selected from the group consisting of molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W) and copper (Cu). The source electrode 140 and the drain electrode 145 may be either a single film or a stack of multiple films.

A via layer 150 may be disposed over the first switching element ST1. The via layer 150 may provide a flat surface over the underlying layers having different heights to facilitate the formation of a first electrode PE.

The via layer 150 may include an inorganic insulating material, or an organic insulating material such as polyacrylate resin, epoxy resin, phenolic resin, polyamide resin, polyimide resin, unsaturated polyesters resin, polyphenylene ether resin, polyphenylene sulfide resin, and benzocyclobutene (BCB). The via layer 150 may be made up of a single film or multiple films of different materials stacked on one another.

The light-emitting element EL may be disposed on the via layer 150. The light-emitting element EL may include a pixel electrode PE, a light emitting layer OL, and a common electrode CE.

The pixel electrode PE may be disposed on the via layer 150. The pixel electrode PE may be disposed in a pattern shape in each of the sub-pixels SPX (see FIG. 3). The pixel electrode PE may be an anode electrode of the light-emitting element EL. The pixel electrode PE may be connected to the drain electrode 145 of the first switching element ST1 through a third contact hole CH3 penetrating the via layer 150.

The pixel electrode PE may be a reflective electrode. The pixel electrode PXE may have a stack structure of a material layer having a high work function such as indium-tin-oxide (ITO), indium-zinc-oxide (IZO), zinc oxide (ZnO), indium tin zinc oxide (ITZO) and indium oxide (In₂O₃); and a reflective material layer such as silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca) or a mixture thereof. A material layer having a higher work function may be disposed in a higher layer than a reflective material layer so that the material layer may be closer to a light emitting layer OL. The pixel electrode PE may have a multilayer structure of ITO/Mg, ITO/MgF, ITO/Ag, and ITO/Ag/ITO, but embodiments are not limited thereto.

A bank layer 155 may be disposed on the pixel electrode PE. The bank layer 155 may include an opening OP exposing (e.g., partially exposing) the pixel electrode PE. The bank layer 155 may be made of an organic insulating material or an inorganic insulating material. For example, the bank layer 155 may include at least one of a photoresist, a polyimide resin, an acrylic resin, a silicon compound, a polyacrylic resin, and the like. The bank layer 155 may represent (or be) black. The bank layer 155 may include a colorant such as a dye and a pigment that represents (or is) black. The bank layer 155 may represent (or be) black to prevent light from being mixed between adjacent sub-pixels.

The light emitting layer OL may be disposed on the pixel electrode PE. The light emitting layer OL may further include one or more of a hole injection layer, a hole transport layer, an electron transport layer, and an electron injection layer. The light emitting layer OL may emit red light, blue light, and green light in different sub-pixels SPX.

The common electrode CE may be disposed on the light emitting layer OL and the bank layer 155. The common electrode CE may be disposed (e.g., entirely disposed) on the display area DPA of the substrate 100. The common electrode CE may be a common electrode disposed across sub-pixels. The common electrode CE may be a cathode electrode of the light-emitting element EL.

The common electrode CE may be translucent or transmissive. In case that the common electrode CE is semi-transmissive, the common electrode CE may include Ag, Mg, Cu, Al, Pt, Pd, Au, Ni, Nd, Ir, Cr, Li, Ca, LiF/Ca, LiF/Al, Mo, Ti or a compound or a mixture thereof, e.g., a mixture of Ag and Mg. Further, in case that the thickness of the common electrode CE ranges from several tens to several hundred angstroms, the common electrode CE may be semi-transmissive.

In case that the common electrode CE is transmissive, the common electrode CE may include a transparent conductive oxide (TCO). For example, the common electrode CE may be formed of tungsten oxide (WₓO_{y}), titanium oxide (TiO₂), indium tin oxide (ITO), indium zinc oxide (IZO), zinc oxide (ZnO), indium tin zinc oxide (ITZO), magnesium oxide (MgO), or a combination thereof.

Hereinafter, a method for fabricating a display device which is used to form a polycrystalline silicon layer included in the semiconductor layer 120 described above will be described.

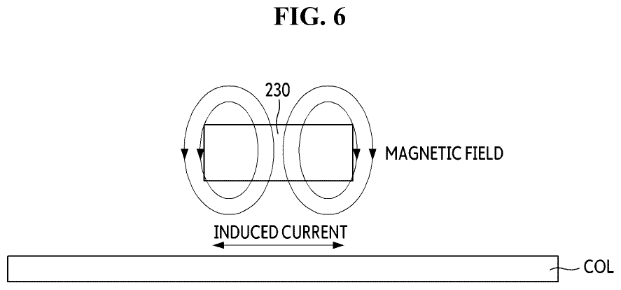

FIG. 5 is a schematic view showing a crystallization device according to an embodiment. FIG. 6 is a view graphically illustrating an operating principle of the crystallization device.

Referring to FIGS. 5 and 6, a crystallization device 200 according to an embodiment may include a microwave input 210, a coupler 220, a dielectric resonator 230, and a body 240.

The microwave input 210 may receive microwaves and transmit the microwaves to the coupler 220. The microwave input 210 may be implemented as a coaxial waveguide. For example, the microwave input 210 may be a rectangular or circular waveguide. However, embodiments are not limited thereto. The microwave input 210 may have a variety of shapes.

The coupler 220 may be connected to the microwave input 210 and may transmit microwaves input through the microwave input 210 to the dielectric resonator 230. The coupler 220 may be formed in a loop shape and may include a metal material. However, embodiments are not limited thereto. The coupler 220 may be formed in a bar shape.

The coupler 220 may adjust the amount of microwaves transmitted to the dielectric resonator 230 by adjusting the distance from the dielectric resonator 230 based on the coupling coefficient of the dielectric resonator 230. Accordingly, the coupler 220 may control so that the microwave energy input through the microwave input 210 may be thoroughly dissipated as heat.

The dielectric resonator 230 may resonate with microwaves input through the microwave input 210 to generate magnetic fields. The dielectric resonator 230 may include a dielectric having a dielectric constant of about 10 or more and a loss tangent of about 0.0005 or less.

The dielectric resonator 230 may be formed in various column shapes, such as a cylindrical shape and a hexahedral shape, and may have a through hole formed in the center portion in the direction of the central axis.

The body 240 of the crystallization device 200 may prevent microwaves from leaking to the outside. The body 240 may adjust the resonance frequency of the magnetic field of the dielectric resonator 230 by adjusting the distance from the dielectric resonator 230.

The body 240 may have an opening on a side so that the magnetic fields generated by the dielectric resonator 230 may be exposed to the substrate. The body 240 may include a metal material that blocks microwaves.

The crystallization device 200 according to an embodiment may be a microwave induction heating annealing device. The microwave induction heating annealing (MIHA) may be a heating method that uses resistance heat caused by induced current generated on a conductive surface by the magnetic fields of microwaves. Microwave induction heating annealing may use a frequency of about 1 MHz to about 300 GHz and generates the magnetic fields necessary for induction heating annealing using the dielectric resonator. For example, by performing the microwave induction heating annealing, the penetration depth of the current induced in the metal by 2.45 GHz microwaves may be several to tens of micrometers, and a metal thin-film may be selectively heated.

As shown in FIG. 6, the dielectric resonator 230 may resonate with microwaves input through the microwave input 210 to generate magnetic fields. The magnetic fields generated by the dielectric resonator 230 generate an induced current in the adjacent conductive layer COL. The conductive layer COL may generate resistance heat by induced current. In the method to be described later, the amorphous silicon layer may be crystallized by generating resistance heat in the metal layer 110 (see FIG. 4).

Hereinafter, a method for fabricating a display device using the crystallization device 200 will be described.

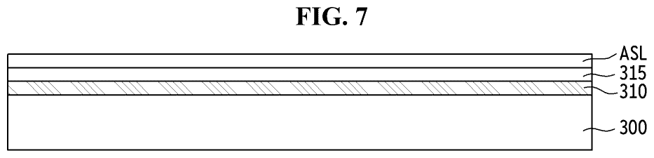

FIGS. 7 to 13 are schematic views showing processing steps of a method of fabricating a display device according to an embodiment. The display device shown in FIGS. 7 to 13 corresponds to the display device shown in FIG. 4.

Referring to FIG. 7, a metal layer 310 may be formed on a substrate 300. The substrate 300 may include a transparent insulating material such as glass, quartz and polymer resin. For example, the substrate 300 may be a glass substrate or a polyimide substrate.

The metal layer 310 may be formed (e.g., entirely disposed) on the substrate 300. For example, the metal layer 310 may be formed by depositing a metal material on the entire surface of the substrate 300. The metal layer 310 may be formed of copper (Cu), aluminum (Al), gold (Au), silver (Ag), titanium (Ti), molybdenum (Mo), tungsten (W), sodium (Na), chromium (Cr), iron (Fe), nickel (Ni), zinc (Zn), neodymium (Nb), tantalum (Ta), or a combination thereof.

The metal layer 310 may have a thickness in a range of about 1 μm to about 300 μm. The thickness of the metal layer 310 may be adjusted within the above range according to the temperature range of the resistance heat of the metal layer 310 in a crystallization process to be described later. For example, in case that the resistance heat of the metal layer 310 is about 1,000° C., the thickness of the metal layer 310 may be in a range of about 35 to about 45 μm. In an embodiment, in case that the resistance heat of the metal layer 310 is about 1,000° C., the thickness of the metal layer 310 may be about 40 μm. For another example, in case that the resistance heat of the metal layer 310 is about 450° C., the thickness of the metal layer 310 may be in a range of about 15 μm to about 20 μm. In an embodiment, in case that the resistance heat of the metal layer 310 is about 450° C., the thickness of the metal layer 310 may be about 18 μm.

Subsequently, a buffer layer 315 may be formed on the metal layer 310, and an amorphous silicon layer ASL may be stacked on the buffer layer 315. The buffer layer 315 may be formed of an organic material, an inorganic material, or a stacked structure thereof. The amorphous silicon layer ASL may be formed by a process such as chemical vapor deposition (CVD) and plasma CVD. For example, the amorphous silicon layer ASL may be formed by a CVD process using SiH₄ gas as the source gas.

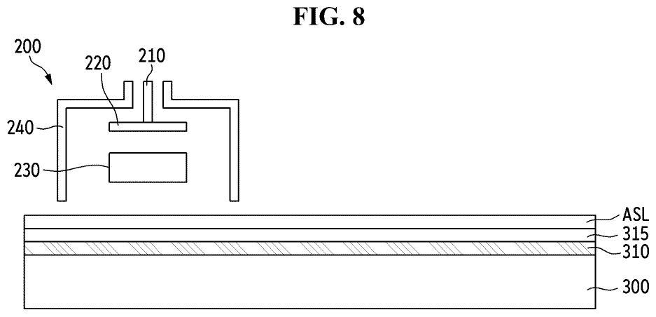

Subsequently, referring to FIG. 8, a crystallization device 200 may be placed above the substrate 300 on which the amorphous silicon layer ASL is formed. The crystallization device 200 may be aligned with a side of the substrate 300. The crystallization device 200 may generate resistance heat in the metal layer 310 of the substrate 300 by generating magnetic fields.

For example, the crystallization device 200 may transmit the microwave input from the microwave input 210 to the coupler 220, and the coupler 220 transmits the received microwave to the dielectric resonator 230. The dielectric resonator 230 may resonate with microwaves to generate magnetic fields.

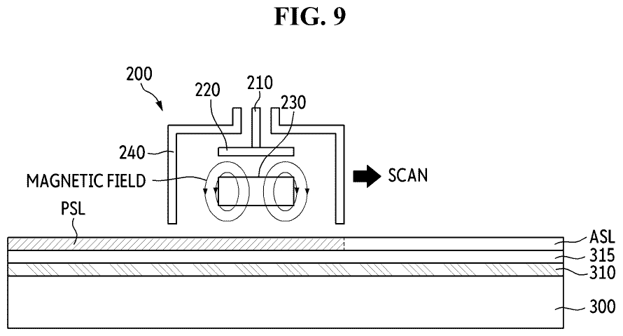

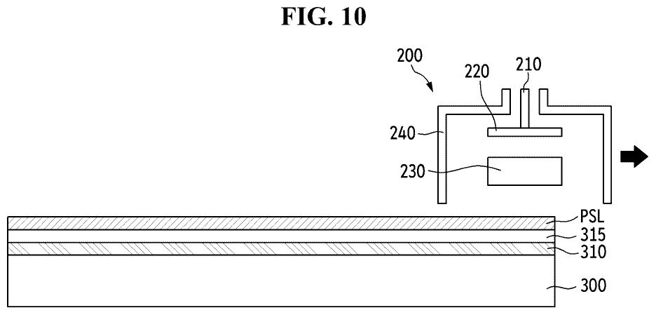

Subsequently, referring to FIGS. 9 and 10, once the crystallization device 200 may be aligned above the substrate 300, microwaves may be input (or supplied) through the microwave input 210 of the crystallization device 200 to generate magnetic fields in the dielectric resonator 230. For example, the microwaves may be input (or supplied) at a frequency in a range of about 1 MHz to about 300 GHz. The input range of the microwave may be adjusted according to process conditions such as the scan speed of the crystallization device 200 and the thickness of the metal layer 310.

An electric current may be induced in the metal layer 310 by the magnetic field generated by the dielectric resonator 230 of the crystallization device 200. For example, an induced current may be generated in the metal layer 310. For example, in case that a microwave of 2.45 GHz is input (or supplied), an induced current may be generated from the upper surface of the metal layer 310 to a depth of about 1.3 μm. In case that an induced current is generated in the metal layer 310, resistance heat may be generated by the induced current.

The crystallization device 200 may move from a side to another side of the substrate 300 at a selected scan speed. The scan speed of crystallization device 200 may range about from about 1 to about 100 mm/s. The scan speed of the crystallization device 200 may be adjusted according to process conditions such as the frequency of the input microwave.

According to an embodiment, in case that a microwave with a frequency of about 2.45 GHz is input (or supplied) and the crystallization device 200 is moved at a scan speed of about 100 mm/s, the resistance heat of about 1,000° C. may be generated from the upper surface of the metal layer 310 to a depth of about 1.3 μm.

The resistance heat in the metal layer 310 may be generated at very high speed. For example, the resistance heat may be generated up to about 1,000° C. or higher per second, but embodiments are not limited thereto. the resistance heat may be adjusted to a temperature lower than about 1,000° C. For example, the resistance heat generated in the metal layer 310 may be in a range of about 400° C. to about 1,000° C. As the resistance heat of the metal layer 310 is generated very quickly, the scan speed of the crystallization device 200 may be increased to about 100 mm/s, thereby improving the tact time of the crystallization process.

Unlike the upper surface of the metal layer 310, relatively low heat may be generated on the lower surface. At the position of about 40 μm from the lower surface of the metal layer 310, the resistance heat of the metal layer 310 may be transmitted heat of about 400° C. or less may be generated. In case that the temperature of the lower surface of the metal layer 310 is lower than the temperature of the upper surface, especially in case that it is about 400° C. or lower, it is possible to prevent damage to the substrate 300. For example, in case that the substrate 300 includes a polymer resin such as polyimide, it is possible to prevent the substrate 300 from being damaged by high heat.

The amorphous silicon layer ASL may be crystallized into polycrystalline silicon by the resistance heat generated in the metal layer 310. As shown in FIG. 9, the amorphous silicon layer ASL after being scanned by the crystallization device 200 may be crystallized into a polycrystalline silicon layer PSL.

The amorphous silicon layer ASL may be crystallized by the high resistance heat of the metal layer 310. According to this embodiment, the resistance heat may be generated in the metal layer 310 by the crystallization device 200 that generates magnetic fields. The metal layer 310 may increase the grain size by uniformly heating throughout the surface of the amorphous silicon layer ASL. For example, by increasing the grain size of the polycrystalline silicon layer PSL, the grain boundaries may be reduced and defects may be reduced. Since a laser is not used, it is possible to prevent hillocks caused by interference of laser beams.

As shown in FIG. 10, once the scan of the crystallization device 200 may be completed from a side to another side of the substrate 300, the amorphous silicon layer ASL may be crystallized into the polycrystalline silicon layer PSL, and thus the crystallization process may be completed.

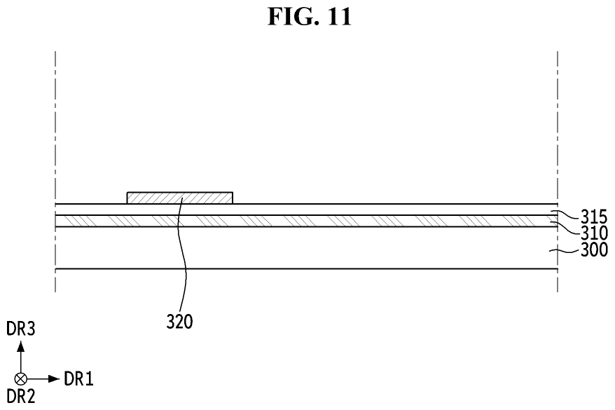

Subsequently, referring to FIG. 11, a semiconductor layer 320 may be formed by patterning the polycrystalline silicon layer PSL. The semiconductor layer 320 may be patterned by a photo process. For example, after forming a mask pattern made of photoresist on the amorphous silicon layer ASL, exposure and development may be carried out, so that the patterned semiconductor layer 320 may be formed.

According to an embodiment, the semiconductor layer 320 may be uniformly crystallized through the high resistance heat of the metal layer 310 using the crystallization device 200, so that the grain size may be increased. As a result, high-speed operation may be possible by increasing electron mobility, defects in the semiconductor layer 320 may be reduced, and leakage current may be prevented.

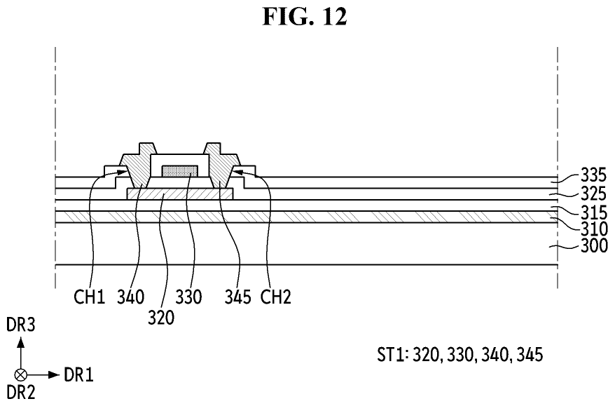

Subsequently, referring to FIG. 12, a gate insulating layer 325 may be formed on the semiconductor layer 320. The gate insulating layer 325 may cover the semiconductor layer 320 and may be formed on the buffer layer 315. The gate insulating layer 325 may be formed by stacking an inorganic material, e.g., silicon oxide, silicon nitride, or silicon oxynitride.

Subsequently, a gate electrode 330 may be formed on the gate insulating layer 325. The gate electrode 330 may be formed to overlap the semiconductor layer 320 in the thickness direction. The gate electrode 330 may be formed by stacking metal, e.g., one or more selected from the group consisting of molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W) and copper (Cu), and patterning it by a photo process.

Subsequently, an interlayer dielectric layer 335 may be formed on the gate electrode 330. The interlayer dielectric layer 335 may cover the gate electrode 330 and may be formed on the gate insulating layer 325. The interlayer dielectric layer 335 may be formed by stacking an inorganic material, e.g., silicon oxide, silicon nitride, or silicon oxynitride.

Subsequently, a first contact hole CH1 and a second contact hole CH2 may be formed in the interlayer dielectric layer 335 and the gate insulating layer 325. The first contact hole CH1 and the second contact hole CH2 may be formed by etching the interlayer dielectric layer 335 and the gate insulating layer 325 to expose the semiconductor layer 320. The first contact hole CH1 may expose a side of the semiconductor layer 320, e.g., a source region, and the second contact hole CH2 may expose another side of the semiconductor layer 320, e.g., a drain region.

Subsequently, a source electrode 340 and a drain electrode 345 may be formed on the interlayer dielectric layer 335. The first contact hole CH1 may be filled with the source electrode 340 that is formed on the interlayer dielectric layer 335. The source electrode 340 may be formed to contact a side of the semiconductor layer 320 exposed by the first contact hole CH1. The drain electrode 345 may be formed on the interlayer dielectric layer 335, and the second contact hole CH2 may be filled with the drain electrode 345. The drain electrode 345 may be formed to contact another side of the semiconductor layer 320 exposed by the second contact hole CH2.

The gate electrode 330 may be formed by stacking metal, e.g., one or more selected from the group consisting of molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W) and copper (Cu), and patterning it by a photo process. In this manner, a first switching element ST1 may be formed, which includes the semiconductor layer 320, the gate electrode 330, the source electrode 340 and the drain electrode 345.

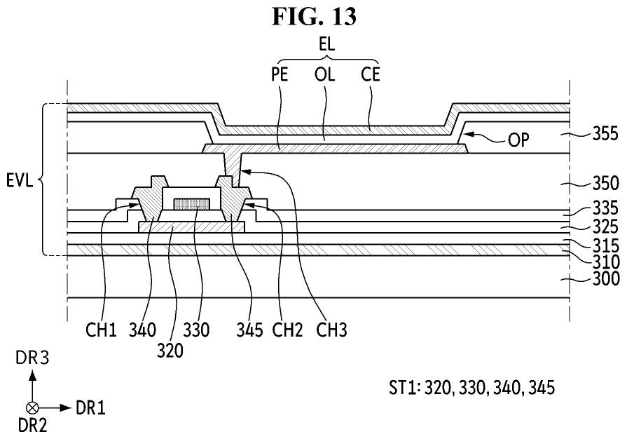

Subsequently, referring to FIG. 13, a via layer 350 may be formed over the first switching element ST1 formed the substrate 300. The via layer 350 may include an inorganic insulating material or an organic insulating material that provides a flat surface over the underlying layers having different heights. For example, the via layer 350 may include an organic insulating material, and may include polyacrylate resin, epoxy resin, phenolic resin, polyamide resin, polyimide resin, unsaturated polyesters resin, poly phenylen ether resin, poly phenylene sulfide resin, benzocyclobutene (BCB), or a combination thereof. The via layer 350 may be formed by a solution process. The solution process may be carried out by, for example, spin coating, slit coating, inkjet printing, etc.

Subsequently, a third contact hole CH3 may be formed in the via layer 350. The third contact hole CH3 may be formed by etching the via layer 350 so that the third contact hole CH3 exposes the drain electrode 345 of the first switching element ST1.

Subsequently, a pixel electrode PE may be formed on the via layer 350. The pixel electrode PE may be formed on the via layer 350, and the third contact hole CH3 may be filled with the pixel electrode PE. The pixel electrode PE may be formed to directly contact the drain electrode 345 exposed by the third contact hole CH3.

The pixel electrode PE may be formed by depositing a material including ITO, IZO, ZnO, ITZO, or indium oxide. For example, the pixel electrode PE may be formed by stacking ITO and then patterning it by a photo process to form a pattern shape.

Subsequently, a bank layer 355 may be formed on the pixel electrode PE and the via layer 350. The bank layer 355 may be formed on the via layer 350 to cover the pixel electrode PE. The bank layer 355 may include an opening OP exposing the pixel electrode PE. For example, the opening OP may be formed by forming the bank layer 355 and then etching a portion of the bank layer 355 by a photo process.

The bank layer 355 may include an organic insulating material that provides a flat surface over the underlying layers having different heights. For example, the bank layer 355 may include at least one of a photoresist, a polyimide resin, an acrylic resin, a silicon compound, a polyacrylic resin, and the like. For example, the bank layer 355 may represent black by including a colorant such as a dye and a pigment that represents (or is) black. The bank layer 355 may be formed by a solution process. The solution process may be carried out by, for example, a spin coating process, a slit coating process, an inkjet printing process, etc.

Subsequently, a light emitting layer OL may be formed on the pixel electrode PE. The light emitting layer OL may be formed by depositing a light-emitting material in the opening OP of the bank layer 355. The light emitting layer OL may further include one or more of a hole injection layer, a hole transport layer, an electron transport layer, and an electron injection layer.

Subsequently, the common electrode CE may be formed on the light emitting layer OL and the bank layer 355. The common electrode CE may be disposed (e.g., entirely disposed) on the light emitting layers OL and the bank layer 355. The common electrode CE may include Ag, Mg, Cu, Al, Pt, Pd, Au, Ni, Nd, Ir, Cr, Li, Ca, LiF/Ca, LiF/Al, Mo, Ti, or a compound or a mixture thereof, e.g., a mixture of Ag and Mg. Accordingly, the light-emitting element EL including the pixel electrode PE, the light emitting layer OL and the common electrode CE may be fabricated.

As described above, the method of fabricating the display device 10 according to an embodiment may crystallize the amorphous silicon layer into the polycrystalline silicon layer by generating resistance heat in the metal layer 310 using the crystallization device 200 that generates magnetic fields. The metal layer 310 may increase the grain size by uniformly heating throughout the surface of the amorphous silicon layer ASL. For example, by increasing the grain size of the polycrystalline silicon layer PSL, the grain boundaries may be reduced and defects may be reduced. Since a laser is not used, it is possible to prevent hillocks caused by interference of laser beams.

For example, the semiconductor layer 320 may be uniformly crystallized by the high resistance heat of the metal layer 310 using the crystallization device 200, so that the grain size may be increased. As a result, high-speed operation may be possible by increasing electron mobility, defects in the semiconductor layer 320 may be reduced, and leakage current may be prevented.

The display device according to an embodiment can be applied to various electronic devices. The electronic device according to the embodiment includes the display device described above, and may further include modules or devices having additional functions in addition to the display device.

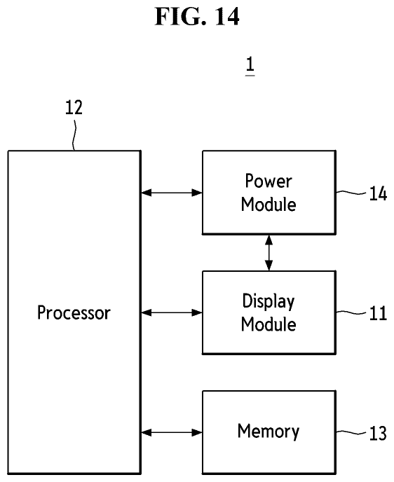

FIG. 14 is a block diagram of an electronic device according to an embodiment.

Referring to FIG. 14, the electronic device 1 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 15 may store data information necessary for the operation of the processor 12 or the display module 11. When the processor 12 executes an application stored in the memory 15, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 1.

At least one of the components of the electronic device 11 according to the embodiment may be included in the display device 10 according to the embodiments. In addition, some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices within the electronic device 11 other than the display device 10.

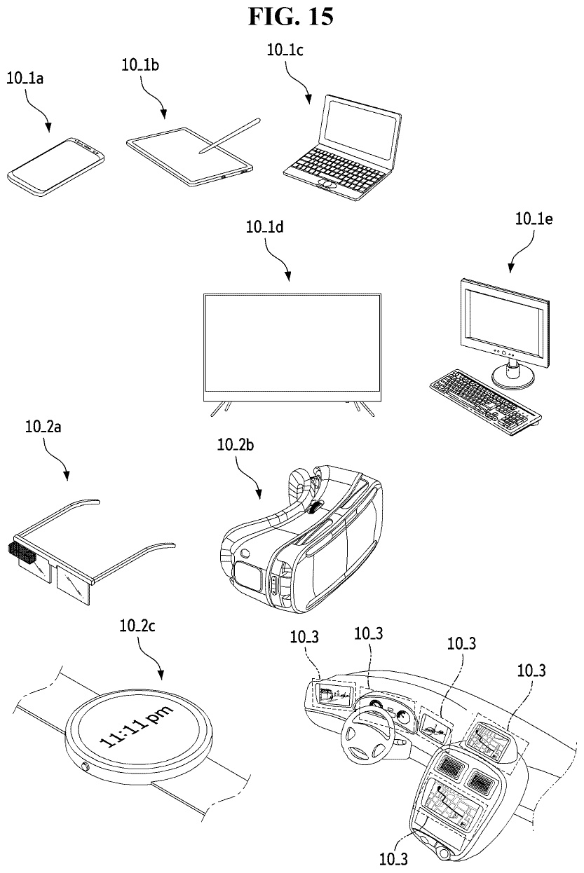

FIG. 15 is a schematic diagram of an electronic device according to various embodiments.

Referring to FIG. 15, various electronic devices to which display devices 10 according to embodiments are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and dashboard of an automobile.

In concluding the detailed description, those skilled in the art will appreciate that many variations and modifications may be made to the preferred embodiments without substantially departing from the principles of the invention. Therefore, the disclosed preferred embodiments of the invention are used in a generic and descriptive sense only and not for purposes of limitation.

What is claimed is:

1. A method of fabricating a display device, the method comprising:
forming a metal layer on a substrate;
forming a buffer layer on the metal layer;
forming an amorphous silicon layer on the buffer layer;
aligning a crystallization device that converts microwaves into magnetic fields above the amorphous silicon layer;
scanning the crystallization device above the amorphous silicon layer to generate resistance heat in the metal layer by the magnetic fields; and
crystallizing the amorphous silicon layer into a polycrystalline silicon layer using the resistance heat of the metal layer.

2. The method of claim 1, wherein a frequency of the microwaves is in a range of about 1 MHz to about 300 GHz.

3. The method of claim 1, wherein the scanning is performed at a scan speed of 1 to 100 mm/s.

4. The method of claim 1, wherein the resistance heat of the metal layer is in a range of about 400° C. to about 1,000° C.

5. The method of claim 1, wherein a grain size of the polycrystalline silicon layer is in a range of about 1 μm to about 10 μm.

6. The method of claim 1, wherein the crystallization device comprises:
a microwave input where microwaves are supplied;
a coupler that adjusts an amount of the microwaves supplied from the microwave input;
a dielectric resonator that is spaced apart from the coupler and generates magnetic fields by resonating with the microwaves transmitted from the coupler; and
a body in which the microwave input, the coupler and the dielectric resonator are disposed.

7. The method of claim 6, wherein the crystallization device is a microwave induction heating annealing device.

8. The method of claim 1, wherein
an induced current is generated in the metal layer by the magnetic fields, and
the resistance heat is generated by the induced current.

9. The method of claim 1, wherein a thickness of the metal layer is in a range of about 1 μm to about 300 μm.

10. The method of claim 1, wherein the buffer layer is formed by stacking an upper layer made of silicon oxide on a lower layer including polyimide.

11. The method of claim 1, further comprising:
patterning the polycrystalline silicon layer to form a semiconductor layer.

12. The method of claim 11, further comprising:
forming a gate insulating layer on the semiconductor layer;
forming a gate electrode overlapping the semiconductor layer on the gate insulating layer;
forming an interlayer dielectric layer on the gate electrode; and
forming a thin-film transistor by forming a source electrode and a drain electrode respectively connected to the semiconductor layer on the interlayer dielectric layer.

13. The method of claim 12, further comprising:
forming a pixel electrode connected to the thin-film transistor on the thin-film transistor;
forming a light emitting layer on the pixel electrode; and
forming a light-emitting element by forming a common electrode on the light emitting layer.

14. A display device comprising:
a substrate;
a metal layer disposed on the substrate;
a buffer layer disposed on the metal layer;
a semiconductor layer disposed on the buffer layer and including polycrystalline silicon;
a gate insulating layer disposed on the semiconductor layer;
a gate electrode disposed on the gate insulating layer;
an interlayer dielectric layer disposed on the gate electrode; and
a source electrode and a drain electrode disposed on the interlayer dielectric layer and respectively connected to the semiconductor layer,
wherein a grain size of the polycrystalline silicon is in a range of about 1 μm to about 10 μm.

15. The display device of claim 14, wherein a thickness of the metal layer is in a range of about 1 μm to about 300 μm.

16. The display device of claim 14, wherein the metal layer is disposed on an entire upper surface of the substrate.

17. The display device of claim 14, wherein the metal layer comprises at least one of copper (Cu), aluminum (Al), gold (Au), silver (Ag), titanium (Ti), molybdenum (Mo), tungsten (W), sodium (Na), chromium (Cr), iron (Fe), nickel (Ni), zinc (Zn), neodymium (Nb), and tantalum (Ta).

18. The display device of claim 14, wherein the buffer layer comprises a lower layer including polyimide and an upper layer made of silicon oxide.

19. The display device of claim 14, further comprising:
a pixel electrode connected to the source electrode or the drain electrode.

20. The display device of claim 19, further comprising:
a light emitting layer disposed on the pixel electrode; and
a common electrode disposed on the light emitting layer.

21. An electronic device, comprising:
a display device that provides an image;
a processor that provides an image data signal to the display device;
a memory that stores a data information for operation; and
a power module that generates power,
wherein the display device comprises:
a substrate;
a metal layer disposed on the substrate;
a buffer layer disposed on the metal layer;
a semiconductor layer disposed on the buffer layer and including polycrystalline silicon;
a gate insulating layer disposed on the semiconductor layer;
a gate electrode disposed on the gate insulating layer;
an interlayer dielectric layer disposed on the gate electrode; and
a source electrode and a drain electrode disposed on the interlayer dielectric layer and respectively connected to the semiconductor layer,
a grain size of the polycrystalline silicon is in a range of about 1 μm to about 10 μm.
